(19) United States
(12) Patent Application Publication
(10) Pub. No.: US 2004/0155349 A1
(43) Pub. Date: Aug. 12, 2004

(54) Semiconductor device and method of fabricating the same

(76) Inventors: Naofumi Nakamura, Tokyo (JP); Hideki Shibata, Yokohama-shi (JP)

Correspondence Address: FROMMER LAWRENCE & HAUG, 745 FIFTH AVENUE- 10TH FL., NEW YORK, NY, 10151, US

(21) Appl. No.: 10/752,642

(22) Filed: Jan. 7, 2004

(30) Foreign Application Priority Data
Jan. 7, 2003 (JP) 2003-001486

(51) Int. Cl. H01L 23/48

(52) U.S. Cl. 257/758

(57) ABSTRACT

A semiconductor device having a multilayer structure is disclosed, which comprises at least two wiring layers, and a via contact formed between the at least two layers and made of the same metal wiring material as the metal wiring material of the at least two wiring layers, wherein the metal wiring material of the via contact contains an additive which is not contained in the metal wiring materials of the at least two wiring layers.

### CROSS-REFERENCE TO RELATED APPLICATIONS

This application is based upon and claims the benefit of priority from the prior Japanese Patent Application No. 2003-001486, filed Jan. 7, 2003, the entire contents of which are incorporated herein by reference.

### BACKGROUND OF THE INVENTION

1. Field of the Invention

The present invention relates to a semiconductor device and a method of fabricating the same, particularly to a wiring structure of a semiconductor device having a multilayer wiring obtained by using the same metal wiring material for particularly at least two wiring layers and a via contact portion formed between the layers and a process of fabricating the semiconductor device, and the semiconductor device and the method of fabricating the same are applied to a low-resistance metal wiring formed in, for example, a damascene process.

2. Description of the Related Art

To fabricate an LSI having a multilayer wiring obtained by laminating two or more wiring layers and connecting the wiring layers each other through a via contact, it is started to practically use forming a low-resistance metal layer (e.g. Cu wiring layer) by using, for example, a damascene process from the viewpoints of lower resistance and high reliability as a wiring to a groove (embedded wiring) and a via contact.

FIGS. 23 to 25 show sectional views of a semiconductor device in major steps in a process of fabricating a conventional semiconductor device having a multilayer metal wiring. Then, a case of forming an embedded metal wiring by using a dual-damascene process is described below. An element-separation-structure forming step and a MOSFET forming step are omitted but steps from a step of forming an embedded first Cu wiring layer up to a step of forming a via contact and a second Cu wiring layer by using the same metal wiring material are disclosed.

First, as shown in FIG. 23, a first wiring groove is formed on a first interlayer insulating film (e.g. TEOS film) 61 deposited on a semiconductor substrate 60 and a first Cu wiring layer 62 is embedded therein. Although not illustrated, a barrier metal is provided between a sidewall of the first wiring groove and the embedded Cu wiring layer 62.

Then, as shown in FIG. 23, a diffusion preventive film (e.g. SiN film) 63 and a second interlayer insulating film 64 are sequentially deposited over the surface of a semiconductor substrate 60 thus formed. The diffusion preventive film 63 has an etching stopper function, a Cu diffusion preventive function, and a Cu oxidation preventive function.

Then, a second wiring groove 71 and a via hole 65 are opened and the diffusion preventive film 63 at the bottom of the via hole is removed by etching. Thereafter, as shown in FIG. 24, a barrier metal 66 is deposited over the surface of the semiconductor substrate 60 and moreover, a Cu film 67 is deposited up to a thickness at which the second wiring groove and the via hole are embedded. In this case, the Cu film 67 is embedded and deposited by forming a seed Cu by the sputtering method and embedding and depositing Cu through plating.

Then, the Cu film 67 is flattened and left only in the via hole and second wiring groove by using a CMP (chemical mechanical polishing) method or the like after heat treatment.

However, in the case of a conventional Cu-damascene-wiring forming step, it is clarified that if the diameter of a via decreases to, for example, about 0.18 μm or less, a problem on reliability occurs that a void 68 is produced at the bottom of a via contact due to a stress as shown in FIG. 25.

Moreover, if a lower Cu wiring layer at the bottom of a via hole is damaged when forming the via hole by, for example, RIE (Reactive Ion Etching) in a damascene process, voids in the lower Cu wiring layer are concentrated at the bottom of THE hole for heat treatment in a Cu embedding step when forming the contact hole and a contact resistance at the bottom of the via hole increases to cause a wiring resistance to increase.

The above heat treatment in the Cu embedding step when forming the via contact is performed to improve the resistance against electro-migration by growing Cu grains and to easily perform CMP in subsequent step.

To prevent the above voids from occurring or the wiring resistance from increasing, heat-treatment conditions (temperature, time and the like) in the Cu embedding step when forming the via hole are optimized. Actually, however, it is difficult to set an optimum value.

However, it is known that atoms in a Cu wiring layer are not easily moved by adding a metal different from Cu to the Cu wiring layer and the resistance against electro-migration is improved. However, the resistivity in the Cu wiring layer is raised by adding additives.

Jpn. Pat. Appln. KOKAI Publication No. 9-289214 discloses a conventional problem and solution on a semiconductor device having a multilayer wiring structure using copper as a main wiring-layer material and a method of fabricating the same.

Jpn. Pat. Appln. KOKAI Publication No. 9-289214 mentions a problem that it is difficult to simultaneously satisfy a low resistance requested for a long-distance wiring and the resistance against the migration in high-density wirings because the resistivity of a copper alloy and the resistance against electro are in a trade-off relation in a semiconductor device having a multilayer wiring structure using copper as a wiring-layer material and a method of fabricating the same.

Jpn. Pat. Appln. KOKAI Publication No. 9-289214 discloses that a lower wiring layer and an intermediate wiring layer are constituted by a copper alloy and an upper wiring layer and a long-distance wiring layer are constituted by pure copper in order to simultaneously satisfy the low resistance and the resistance against the electro-migration. Moreover, the publication discloses that a lower first wiring layer is constituted by a copper alloy and an upper second wiring layer is constituted by a copper alloy having a ratio of a composition such as an additive lower than that of the first wiring layer. Furthermore, the publication discloses that the joint for connecting the first or second wiring layer with another wiring layer is constituted by a copper alloy having the composition ratio of an additive higher than the composition ratio of additives of the upper wiring layer connected to the joint.

However, Jpn. Pat. Appln. KOKAI Publication No. 9-289214 does not disclose the type of or the quantity of additives to copper at the joint between the lower first wiring layer and the higher second wiring layer in detail when constituting the both wiring layers by the same pure copper or the same copper alloy.

As described above, to manufacture a multilayer wiring using a conventional Cu embedded wiring, there is a problem that a reliability is deteriorated and a wiring resistance is increased due to drawing-up of a via when the diameter of the via decreases.

### BRIEF SUMMARY OF THE INVENTION

According to an aspect of the present invention, there is provided a semiconductor device having a multilayer structure, comprising:

at least two wiring layers; and

a via contact formed between the at least two layers and made of a metal wiring material which is the same as that of the at least two wiring layers,

wherein the metal wiring material of the via contact contains an additive which is not contained in the metal wiring materials of the at least two wiring layers.

According to another aspect of the present invention, there is provided a semiconductor device having a multilayer structure, comprising:

at least two wiring layers; and

a via contact formed between the at least two layers and made of a metal wiring material which is the same as that of the at least two wiring layers,

wherein metal wiring materials of the at least two wiring layers contain at least one additive, and

a metal wiring material of the via contact contains at least two additives which include an additive which is the same as that contained in the metal wiring materials of the at least two wiring layers.

According to a further aspect of the present invention, there is provided a semiconductor device having a multilayer structure, comprising:

at least two wiring layers; and

a via contact formed between the at least two layers and made of a metal wiring material which is the same as that of the at least two wiring layers,

wherein metal wiring materials of the at least two wiring layers and a metal wiring material of the via contact contain the same additive, and

a concentration of the same additive in metal wiring material of the via contact is higher than that of the same additive in the metal wiring materials of the at least two wiring layers.

According to a further aspect of the present invention, there is provided a semiconductor device having a multilayer structure, comprising:

at least two wiring layers; and

a via contact formed between the at least two layers and made of a metal wiring material which is the same as that of the at least two wiring layers,

wherein metal wiring materials of the at least two wiring layers contain at least one additive, and

a metal wiring material of the via contact contains at least two additives which include an additive which is the same as that contained in the metal wiring materials of the at least two wiring layers, and

a concentration of the at least one additive commonly contained in the metal wiring materials of the at least two wiring layers and the metal wiring material of the via contact is higher in the metal wiring material of the via contact than in the metal wiring materials of the at least two wiring layers.

According to a further aspect of the present invention, there is provided a semiconductor device comprising:

a first metal wiring layer made of a first wiring material, formed in a first wiring groove formed in a first insulating film on a semiconductor substrate;

a second insulating film on the first insulating film having the first wiring layer embedded therein;

a via contact embedded in a via hole formed in the second insulating film, the via contact being made of the same wiring material as the first wiring material, which contain an additive which is not contained in the first wiring material of the first wiring layer;

a third insulating film on the second insulating film having the via contact formed therein; and

a second metal wiring layer embedded in a second wiring groove formed in the third insulating film, the second metal wiring layer being made of the same metal wiring material as the metal wiring material of the first metal wiring layer;

According to a further aspect of the present invention, there is provided a semiconductor device comprising:

a first metal wiring layer made of a first wiring material added with an additive, formed in a first wiring groove formed in a first insulating film on a semiconductor substrate;

a second insulating film on the first insulating film having the first wiring layer embedded therein;

a via contact embedded in a via hole formed in the second insulating film, the via contact being made of the first wiring material which contains the additive; and

a third insulating film on the second insulating film having the via contact formed therein; and

a second metal wiring layer embedded in a second wiring groove formed in the third insulating film, the second metal wiring layer being made of the metal wiring material which contains the additive,

wherein a concentration of the additive in the metal wiring material of the via contact is higher than that of the additive in the metal wiring materials of the first metal wiring layer and the second metal wiring layer.

According to a further aspect of the present invention, there is provided a method of manufacturing a semiconductor device, comprising:

forming a first wiring layer made of a metal wiring material in a first wiring groove formed in a first insulating film on a semiconductor substrate;

forming a second insulating film on the first insulating film having the first wiring layer formed therein;

forming a via hole in the second insulating film;

forming a first barrier metal over the surface of the second insulating film including the via hole;

forming a first metal film formed of the metal wiring material over the surface of the first barrier metal to embed the metal wiring material in the via hole;

forming a via contact formed of the first metal film and first barrier metal on the via hole by removing the first metal film and first barrier metal from portions other than the inside of the via hole;

forming a third insulating film over the surface of the second insulating film having the via contact formed thereon;

forming a second wiring groove in the third insulating film;

forming a second barrier metal over the surface of the third insulating film including the second wiring groove;

forming a second metal film formed from the first metal material over the surface of the second barrier metal; and

forming a second wiring layer formed by residual portions of the second metal film and second barrier metal in the second wiring groove by removing the portions of the second metal film and second barrier metal deposited on the third insulating film,

wherein the metal wiring material of the first metal film contains an additive which is not contained in the metal wiring materials of the first wiring layer and the second metal film.

According to a further aspect of the present invention, there is provided a method of manufacturing a semiconductor device, comprising:

forming a first wiring layer made of a metal wiring material added with an additive in a first wiring groove formed in a first insulating film on a semiconductor substrate;

forming a second insulating film on the first insulating film having the first wiring layer formed therein;

forming a via hole in the second insulating film;

forming a first barrier metal over the second insulating film including the via hole;

forming a first metal film made of the metal wiring material added with the additive over the first barrier metal to embed the via hole with the metal wiring material added with the additive;

removing the first metal film and the first barrier metal from portions other than the inside of the via hole to form a via contact formed of the first metal film added with the additive in the via hole;

forming a third insulating film over the surface of the second insulating film having the via contact formed thereon;

forming a second wiring groove in the third insulating film;

forming a second barrier metal over the third insulating film including the second wiring groove;

forming a second metal film made of the metal wiring material added with the additive over the second barrier metal; and

removing the portions of the second metal film and second barrier metal on the third insulating film to form a second wiring layer formed of the second metal film added with the additive in the second wiring groove,

wherein a concentration of the additive in the metal wiring material of the first metal film of the via contact is higher than that of the additive in the metal wiring material of the first wiring layer and the metal wiring material of the second metal film.

According to a further aspect of the present invention, there is provided a method of manufacturing a semiconductor device, comprising:

forming a first wiring layer made of a metal wiring material in a first wiring groove formed in a first insulating film on a semiconductor substrate;

forming a second insulating film on the first insulating film having the first wiring layer formed therein;

forming a via hole in the second insulating film;

forming a first barrier metal over the second insulating film including the via hole;

forming a first metal film made of the metal wiring material over the first barrier metal to embed the via hole with the metal wiring material added with the additive;

removing the first metal film and the first barrier metal from portions other than the inside of the via hole to form a via contact formed of the first metal film in the via hole;

forming a third insulating film over the surface of the second insulating film having the via contact formed thereon;

forming a second wiring groove in the third insulating film;

forming a second barrier metal over the third insulating film including the second wiring groove;

forming a second metal film made of the metal wiring material over the second barrier metal; and

removing the portions of the second metal film and second barrier metal on the third insulating film to form a second wiring layer formed of the second metal film in the second wiring groove,

wherein metal wiring materials of the first wiring layer and the second wiring layer contain at least one additive, and the metal wiring material of the first metal film contains at least two additives which include the at least one additive.

According to a further aspect of the present invention, there is provided a method of manufacturing a semiconductor device, comprising:

forming a first wiring layer made of a metal wiring material in a first wiring groove formed in a first insulating film on a semiconductor substrate;

forming a second insulating film on the first insulating film having the first wiring layer formed therein;

forming a via hole in the second insulating film;

forming a first barrier metal over the second insulating film including the via hole;

forming a first metal film made of the metal wiring material over the first barrier metal to embed the via hole with the metal wiring material;

removing the first metal film and the first barrier metal from portions other than the inside of the via hole to form a via contact formed of the first metal film in the via hole;

forming a third insulating film over the surface of the second insulating film having the via contact formed thereon;

forming a second wiring groove in the third insulating film;

forming a second barrier metal over the third insulating film including the second wiring groove;

forming a second metal film made of the metal wiring material over the second barrier metal to embed the second wiring groove with the metal wiring material; and

removing the portions of the second metal film and second barrier metal on the third insulating film to form a second wiring layer formed of the second metal wiring layer in the second wiring groove,

wherein metal wiring materials of the first wiring layer and the second wiring layer contain at least one additive, and

the metal wiring material of the first metal film contains at least two additives which include the at least one additive.

wherein a concentration of the at least one additive in the metal wiring material of the first metal film is higher than that of the at least one additive in the metal wiring material of the first wiring layer and the metal wiring material of the second metal film.

According to a further aspect of the present invention, there is provided a method of manufacturing a semiconductor device, comprising:

forming a first wiring layer made of a metal wiring material in a first wiring groove formed in a first insulating film on a semiconductor substrate;

forming a second insulating film on the first insulating film having the first wiring layer formed therein;

forming a via hole in the second insulating film;

forming a first barrier metal over the second insulating film including the via hole;

forming a first metal film made of the metal wiring material over the first barrier metal to embed the via hole with the metal wiring material;

forming a substance layer containing an additive which is not contained in the metal wiring material of the first wiring layer over the first metal film;

heating to diffuse the additive contained in the substance layer into first metal film;

removing the substance layer as well as the first metal film and the first barrier metal from portions other than the inside of the via hole to form a via contact formed of the first metal film containing the additive in the via hole;

forming a third insulating film over the surface of the second insulating film having the via contact formed thereon;

forming a second wiring groove in the third insulating film;

forming a second barrier metal over the third insulating film including the second wiring groove;

forming a second metal film made of the metal wiring material over the second barrier metal; and

removing the portions of the second metal film and second barrier metal on the third insulating film to form a second wiring layer formed of the second metal film in the second wiring groove.

### BRIEF DESCRIPTION OF THE SEVERAL VIEWS OF THE DRAWING

FIG. 1 is a cross sectional view of a part of a semiconductor device according to a first embodiment of the present invention in a step of fabricating the semiconductor device;

FIG. 2 is a cross sectional view of the part of the semiconductor device according to the first embodiment of the present invention in a step following the step shown in FIG. 1 of fabricating the semiconductor device;

FIG. 3 is a cross sectional view of the part of the semiconductor device according to the first embodiment of the present invention in a step following the step shown in FIG. 2 of fabricating the semiconductor device;

FIG. 4 is a cross sectional view of the part of the semiconductor device according to the first embodiment of the present invention in a step following the step shown in FIG. 3 of fabricating the semiconductor device;

FIG. 5 is a cross sectional view of the part of the semiconductor device according to the first embodiment of the present invention in a step following the step shown in FIG. 4 of fabricating the semiconductor device;

FIG. 6 is a cross sectional view of the part of the semiconductor device according to the first embodiment of the present invention in a step following the step shown in FIG. 5 of fabricating the semiconductor device;

FIG. 7 is an illustration showing characteristics between a metal to be added and the specific resistivity of Cu;

FIG. 8 is a cross sectional view of a part of a semiconductor device according to second to fourth embodiments of the present invention in a step of fabricating the semiconductor device;

FIG. 9 is a cross sectional view of the part of the semiconductor device according to the second embodiment of the present invention in a step following the step shown in FIG. 8 of fabricating the semiconductor device;

FIG. 10 is a cross sectional view of the part of the semiconductor device according to the second embodiment of the present invention in a step following the step shown in FIG. 9 of fabricating the semiconductor device;

FIG. 11 is a cross sectional view of the part of the semiconductor device according to the second embodiment of the present invention in a step following the step shown in FIG. 10 of fabricating the semiconductor device;

FIG. 12 is a cross sectional view of the part of the semiconductor device according to the second embodiment of the present invention in a step following the step shown in FIG. 11 of fabricating the semiconductor device;

FIG. 13 is a cross sectional view of the part of the semiconductor device according to the second embodiment of the present invention in a step following the step shown in FIG. 12 of fabricating the semiconductor device;

FIG. 14 is a cross sectional view of the part of the semiconductor device according to the second embodiment of the present invention in a step following the step shown in FIG. 13 of fabricating the semiconductor device;

FIG. 15 is a cross sectional view of a part of a semiconductor device according to a fifth embodiment of the present invention in a step of fabricating the semiconductor device;

FIG. 16 is a cross sectional view of the part of the semiconductor device according to the fifth embodiment of the present invention in a step following the step shown in FIG. 15 of fabricating the semiconductor device;

FIG. 17 is a cross sectional view of a part of a semiconductor device according to a sixth embodiment of the present invention in a step of fabricating the semiconductor device;

FIG. 18 is a cross sectional view of the part of the semiconductor device according to the sixth embodiment of the present invention in a step following the step shown in FIG. 17 of fabricating the semiconductor device;

FIG. 19 is a cross sectional view of the part of the semiconductor device according to the sixth embodiment of the present invention in a step following the step shown in FIG. 18 of fabricating the semiconductor device;

FIG. 20 is a cross sectional view of a part of a semiconductor device according to a seventh embodiment of the present invention in a step of fabricating the semiconductor device;

FIG. 21 is a cross sectional view of the part of the semiconductor device according to the seventh embodiment of the present invention in a step following the step shown in FIG. 20 of fabricating the semiconductor device;

FIG. 22 is a cross sectional view of the part of the semiconductor device according to the seventh embodiment of the present invention in a step following the step shown in FIG. 21 of fabricating the semiconductor device;

FIG. 23 is a cross sectional view of a part of a conventional semiconductor device in a step of fabricating the semiconductor device;

FIG. 24 is a cross sectional view of the part of the conventional semiconductor device in a step following the step shown in FIG. 23 of fabricating the semiconductor device; and

FIG. 25 is a cross sectional view of the part of the conventional semiconductor device in a step following the step shown in FIG. 24 of fabricating the semiconductor device.

### DETAILED DESCRIPTION OF THE INVENTION

Embodiments of the present invention will be described below by referring to the accompanying drawings.

<First Embodiment>

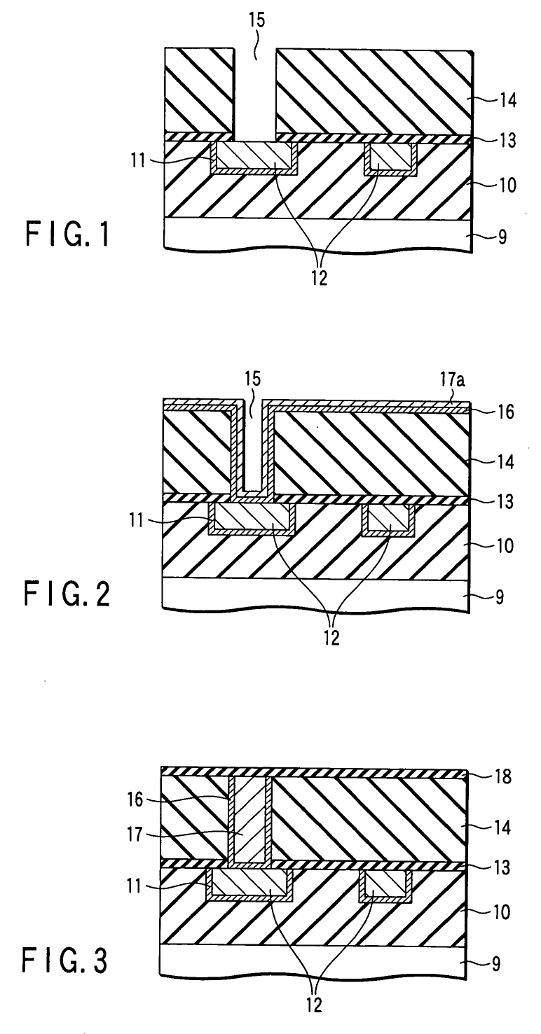

FIGS. 1 to 6 show sectional views of a semiconductor device in major steps in a process of fabricating a semiconductor device having a multilayer metal wiring according to a first embodiment of the present invention.

This embodiment describes a case of forming an embedded metal wiring by using a single-damascene process. An element-separation-structure forming step and a MOSFET forming step are omitted but steps from a step of forming an embedded first Cu wiring up to a step of forming a via contact and a second Cu wiring layer by using the same metal wiring material are disclosed.

In the embodiment, an additive which is not contained in the metal wiring material of the upper wiring layer (second Cu wiring 22) or the metal wiring material of the lower wiring layer (first Cu wiring 12) is contained in the metal wiring material of the via contact 17. Sn is used as the additive.

First, as shown in FIG. 1, a first wring groove is formed on a fist interlayer insulating film (e.g. TEOS film) 10 deposited on a semiconductor substrate 9 and embedded with a first Cu wiring 12. A barrier metal 11 is provided between a sidewall of the first wiring groove and the embedded Cu wiring layer 12. Moreover, a first diffusion preventive film (e.g. SiN film or SiC film) 13 and a second interlayer insulating film (e.g. TEOS film) 14 are sequentially deposited over the surface of the semiconductor substrate 9 thus formed. The first diffusion preventive film 13 has an etching stopper function, a Cu diffusion preventive function, and a Cu oxidation preventive function.

Then, a resist is applied onto the second interlayer insulating film 14 and patterned to form a resist pattern and a via hole 15 is formed on the second interlayer insulating film 14 by the RIE using the formed resist pattern as a mask. Thereafter, the resist pattern is removed. Then, the first diffusion preventive film 13 at the bottom of the via hole 15 is removed by etching.

Then, as shown in FIG. 2, a refractory metal (e.g. Ta film, TaN film, or TiN) is deposited over the surface of the semiconductor substrate 9 as a first barrier metal 16 (barrier metal of via contact portion) up to a thickness of about 20 nm by the sputtering method. Moreover, CuSn(1%) 17a obtained by adding 1%, for example, of Sn into Cu is deposited up to a thickness of about 100 nm as a seed metal of the via contact portion by the sputtering method. In this case, Sn can be easily added into Cu by adding Sn into a target metal by the sputtering method. The quantity of Sn to be added must be kept in the tolerance of the increased value of a wiring resistance due to addition of Sn.

Subsequently, the refractory metal film 16 and CuSn(1%) film 17a on the second interlayer insulating film 14 are removed by the CMP method or the like, and the films 16 and 17a are left only on an inside wall of the contact hole 15 as the first barrier metal 16 and the seed metal 17a of the via contact portion, respectively.

Next, as shown in FIG. 3, a Cu film of about 400 nm is deposited over the surface of the semiconductor substrate 9, that is, on the second interlayer insulating film 14 including the inside of the via hole 15 by the electrolytic plating method. Then, the whole Cu film is flattened by the CMP method and the Cu film on the second interlayer insulating film 14 is removed and the Cu film is left only in the via hole 15 as a via contact 17. At this Cu deposition, Sn in the CuSn(1%) film 17a is diffused into the via contact 17. This is substantially equivalent to the fact that Sn is added. After the Cu deposition, a heat treatment may be carried out to further diffuse Sn into the via contact 17.

Thereafter, a second diffusion preventive film (e.g. SiN film or SiC film) 18 having an etching stopper function, a Cu diffusion preventive function, and a Cu oxidation preventive function is deposited over the surface of the semiconductor substrate 9, that is, on the via contact 17 and second interlayer insulating film 14.

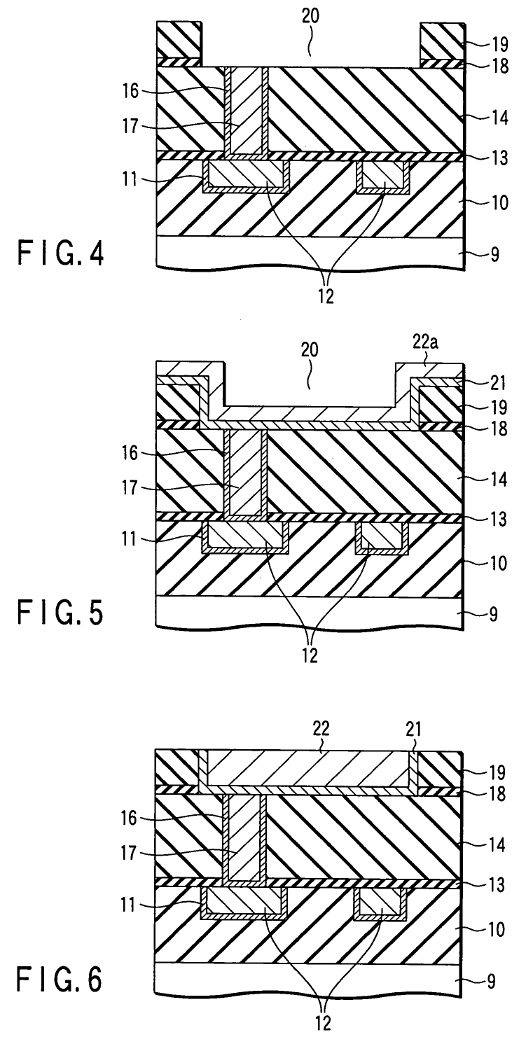

Subsequently, as shown in FIG. 4, a third interlayer insulating film 19 having a low relative permittivity to be formed into an interlayer insulating film for a second metal wiring is deposited on the second diffusion preventive film 18. Then, a resist is applied onto the interlayer insulating film 19 and patterned to form a resist pattern and a second wiring groove 20 in which the second Cu wiring layer is to be embedded is formed on the third interlayer insulating film 19 by the RIE using the formed resist pattern as a mask.

Next, the diffusion preventive film 18 at the bottom of the second wiring groove 20 is removed by etching. Then, as shown in FIG. 5, a refractory metal (e.g. Ta film, TaN film, or TiN film) is deposited over the surface of the semiconductor substrate 9 as a second barrier metal 21 (barrier metal of wiring groove portion) by the sputtering method. Moreover, seed Cu is deposited on the second barrier metal 21 as a seed metal 22a of the wiring groove portion by the sputtering method. Sn is not added into the seed Cu.

Then, a Cu film of about 400 nm is deposited over the surface of the third interlayer insulating film 19 including the inside of the wiring groove 20 by the electrolytic plating method. Thereafter, the whole Cu film is flattened by using the CMP method and the Cu film is left only in the wiring groove as a second Cu wiring layer 22 as shown in FIG. 6. Because Sn in the CuSn(1%) film 17a is added in the second Cu wiring layer 22 left in the wiring groove, this is substantially equivalent to the fact that Sn is added.

Subsequently, it is possible to form a plurality of multilayer wirings more than two wirings by depositing a diffusion preventive film (not shown) and repeating the above-mentioned steps while referring to FIGS. 4 to 6.

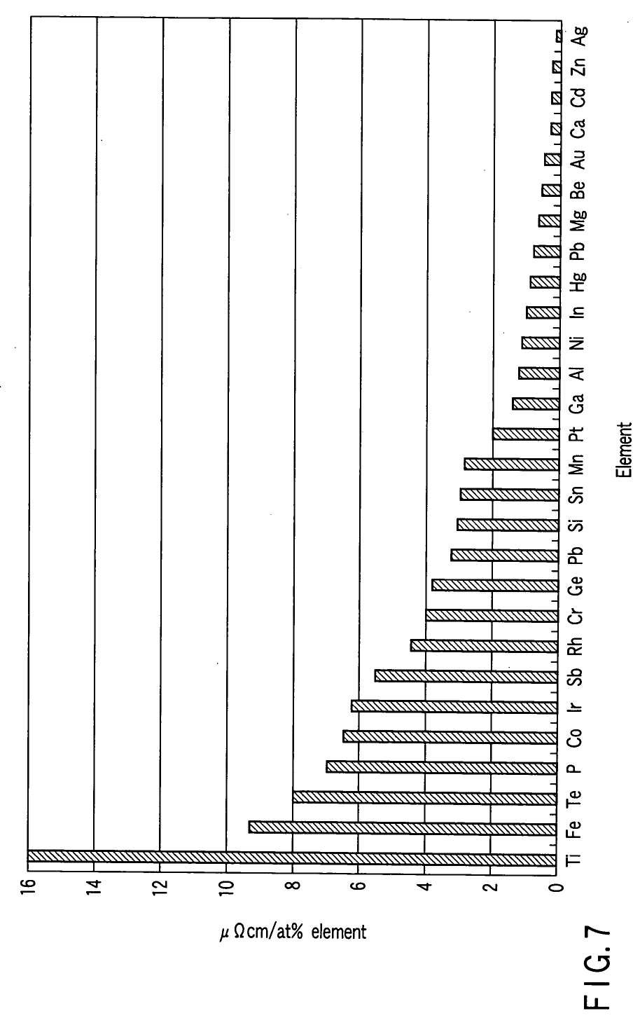

FIG. 7 is a characteristic graph showing that a resistivity of Cu increases by adding a metal to Cu, and the resistivity changes in accordance with the type of a metal added.

As shown in FIG. 7, the increase of resistivity depends on the type of a metal to be added to Cu (resistivity of about 2 μΩ). Thus, a type of metal is selected by comprehensively considering the required resistivity, the easiness of introduction and the like into an actual fabrication process.

Specifically, when a wiring material is Cu, any of the following substances shown in FIG. 7 is used as an additive: Sn, Rh, Zn, Al, Ru, Cr, Pd, In, Mg, Co, Zr, Ti, Ag, Ir, Ni, Ge, Nb, B, and Hf. It is preferable to use one of Sn, Rh, and Zn by comprehensively considering the easiness for execution and the like.

That is, according to the first embodiment, the additive Sn which is not contained in the wiring layer 12 or 22 is contained in the via contact 17 of a semiconductor device having a multilayer wiring structure constituted by using the same metal wiring material Cu for at least two wiring layers 12 and 22 and the via contact 17 formed between the layers 12 and 22. Thus, it is possible to improve the resistance against migration at the via contact 17 while preventing wiring resistances of the wiring layers 12 and 22 from rising. In place of Sn, any the following substances is used as additives to be added to the wiring material of the via contact 17: Rh, Zn, Al, Ru, Cr, Pd, In, Mg, Co, Zr, Ti, Ag, Ir, Ni, Ge, Nb, B, and Hf. When Al is used as a metal wiring material, it is preferable to use either of Cu and Si by comprehensively considering the magnitude of the resistivity and the easiness of introduction into the actual fabrication process.

Moreover, when Ag is used as a metal wiring material, it is preferable to use Cu by comprehensively considering the magnitude of the resistivity and the easiness of introduction into the actual fabrication process.

Furthermore, it is possible to form the wiring layer 22 by using not only the embedded wiring method according to the above damascene process but also the well-known dry etching method. In addition, it is possible to form the via contact 17 or wiring layer 22 by not only a combination of the sputtering method and electrolytic plating method but also a proper combination of the chemical vapor deposition (CVD) method which is superior in step coverage, PVD method, electrolytic plating method, and electroless plating method.

<Second Embodiment>

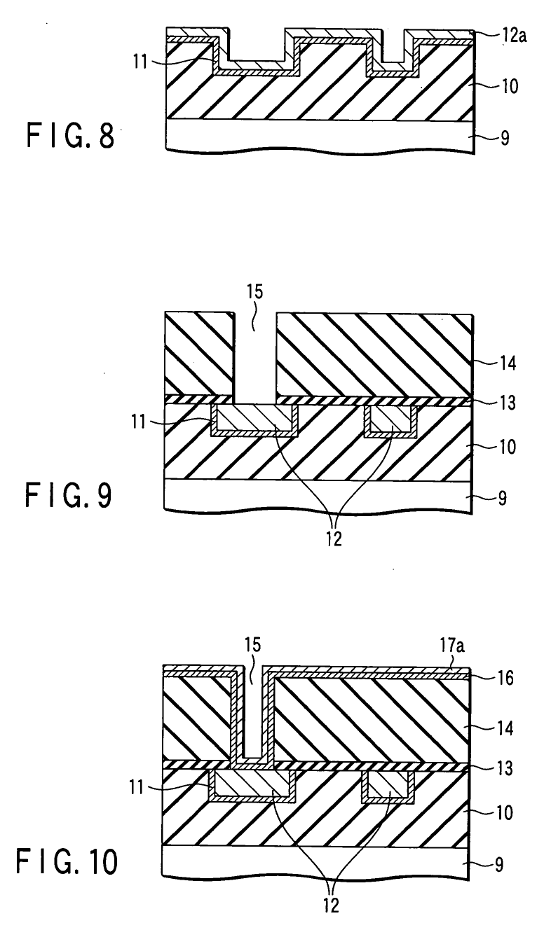

FIGS. 8 to 14 show sectional views of a semiconductor device in major steps in a process of fabricating a semiconductor device having a multilayer metal wiring according to a second embodiment of the present invention.

As with the first embodiment, this embodiment describes a case of forming an embedded metal wiring by using a single-damascene process. An element-separation-structure forming step and a MOSFET forming step are omitted but steps from a step of forming an embedded first Cu wiring up to a step of forming a via contact and a second Cu wiring layer by using the same metal wiring material are disclosed.

In the embodiment, the metal wiring materials of the upper wiring layer (second Cu wiring 22) and the metal wiring material of the lower wiring layer (first Cu wiring 12) contain at least one additive. The metal wiring material of the via contact 17 contains at least two additives including the same additive or additives as the metal wiring materials of the upper wiring layer and the lower wiring layer. The at least two additives are of different kinds or types. In the embodiment, the at least one additive is, for example, Sn, and the at least two additives are, for example, Sn and Rh.

In the manufacturing method, first, as shown in FIG. 1, a first wring groove is formed on a first interlayer insulating film (e.g. TEOS film) 10 deposited on a semiconductor substrate 9.

Then, a refractory metal (e.g. Ta film, TaN film, or TiN) is deposited over the surface of the semiconductor substrate 9 as a barrier metal up to a thickness of about 20 nm by the sputtering method. Moreover, CuSn(1%) obtained by adding 1% of Sn into Cu is deposited up to a thickness of about 100 nm as a seed metal 12a of a first wiring portion by the sputtering method. In this case, Sn can be easily added into Cu by adding Sn into a target metal by the sputtering method. The quantity of Sn to be added must be kept in the tolerance of the increased value of a wiring resistance due to addition of Sn.

Subsequently, the refractory metal film 11 and CuSn(1%) film 12a on the first interlayer insulating film 10 are removed by the CMP method or the like, and the films 11 and 12a are left only on an inside wall of the first wiring groove as the first barrier metal and the seed metal of the first wiring portion, respectively.

Next, a Cu film of about 400 nm is deposited over the surface of the semiconductor substrate 9, that is, on the first interlayer insulating film 14 including the inside of the first wiring groove by the electrolytic plating method. Then, the whole Cu film is flattened by the CMP method and the Cu film on the first interlayer insulating film 10 is removed and, as shown in FIG. 9, the Cu film is left only in the first wiring groove as a first wiring layer 12. At this Cu deposition, Sn in the CuSn(1%) film 12a left in the first wiring groove is diffused into the first wiring layer 12. This is substantially equivalent to the fact that Sn is added.

Thereafter, a first diffusion preventive film (e.g. SiN film or SiC film) 13 having an etching stopper function, a Cu diffusion preventive function, and a Cu oxidation preventive function is deposited over the surface of the semiconductor substrate 9, that is, on the first wiring groove and the first interlayer insulating film 10. Then, a second interlayer insulating film (e.g. TEOS film) 14 is deposited over the first diffusion preventive film (e.g. SiN film or SiC film) 13.

Subsequently, a resist is applied onto the second interlayer insulating film 14 and patterned to form a resist pattern, not shown, and a via hole 15 is formed in the second interlayer insulating film 14 by the RIE using the formed resist pattern as a mask. Then, the formed resist pattern is removed. Next, the first diffusion preventive film 13 at the bottom of the via hole 15 is removed by etching.

Then, as shown in FIG. 10, a refractory metal (e.g. Ta film, TaN film, or TiN) is deposited over the surface of the semiconductor substrate 9 as a first barrier metal 16 (a barrier metal of the via contact portion) up to a thickness of about 20 nm by the sputtering method. Moreover, CuSn(1%)Rh(1%) 17a obtained by adding 1%, for example, of Sn and Rh into Cu is deposited up to a thickness of about 100 nm as a seed metal of the via contact portion by the sputtering method. In this case, Sn and Rh can be easily added into Cu by adding Sn and Rh into a target metal by the sputtering method. The quantity of Sn and Rh to be added must be kept in the tolerance of the increased value of a wiring resistance due to addition of Sn and Rh.

Subsequently, the refractory metal film 16 and CuSn(1%)Rh(1%) film 17a on the second interlayer insulating film 14 are removed by the CMP method or the like, and the films 16 and 17a are left only on an inside wall of the contact hole 15 as the first barrier metal 16 and the seed metal 17a of the via contact portion, respectively.

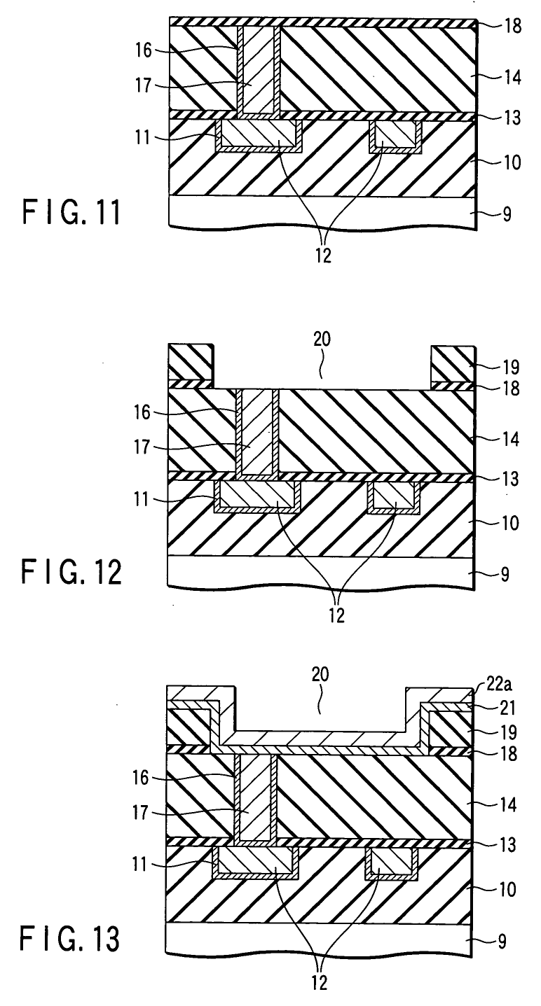

Next, as shown in FIG. 11, a Cu film of about 400 nm is deposited over the surface of the semiconductor substrate 9, that is, on the second interlayer insulating film 14 including the inside of the via hole 15 by the electrolytic plating method. Then, the whole Cu film is flattened by the CMP method and the Cu film on the second interlayer insulating film 14 is removed and the Cu film is left only in the via hole 15 as a via contact 17. At this Cu deposition, Sn and Rh in the CuSn(1%)Rh(1%) film 17a are diffused into the via contact 17. This is substantially equivalent to the fact that Sn and Rh are added.

Thereafter, a second diffusion preventive film (e.g. SiN film or SiC film) 18 having an etching stopper function, a Cu diffusion preventive function, and a Cu oxidation preventive function is deposited over the surface of the semiconductor substrate 9, that is, on the via contact 17 and second interlayer insulating film 14.

Subsequently, as shown in FIG. 12, a third interlayer insulating film 19 having a low relative permittivity to be formed into an interlayer insulating film for a second metal wiring is deposited on the second diffusion preventive film 18. Then, a resist is applied onto the interlayer insulating film 19 and patterned to form a resist pattern and a second wiring groove 20 in which the second Cu wiring layer is to be embedded is formed on the third interlayer insulating film 19 by the RIE using the formed resist pattern as a mask.

Next, the diffusion preventive film 18 at the bottom of the second wiring groove 20 is removed by etching. Then, as shown in FIG. 13, a refractory metal (e.g. Ta film, TaN film, or TiN film) is deposited over the surface of the semiconductor substrate 9 as a second barrier metal 21 (barrier metal of wiring groove portion) by the sputtering method. Moreover, CuSn(1%) obtained by adding 1%, for example, of Sn into Cu is deposited up to a thickness of about 100 nm on the second barrier metal 21 as a seed metal 22a of the second wiring groove portion by the sputtering method. In this case, Sn can be easily added into Cu by adding Sn into a target metal by the sputtering method. The quantity of Sn to be added must be kept in the tolerance of the increased value of a wiring resistance due to addition of Sn.

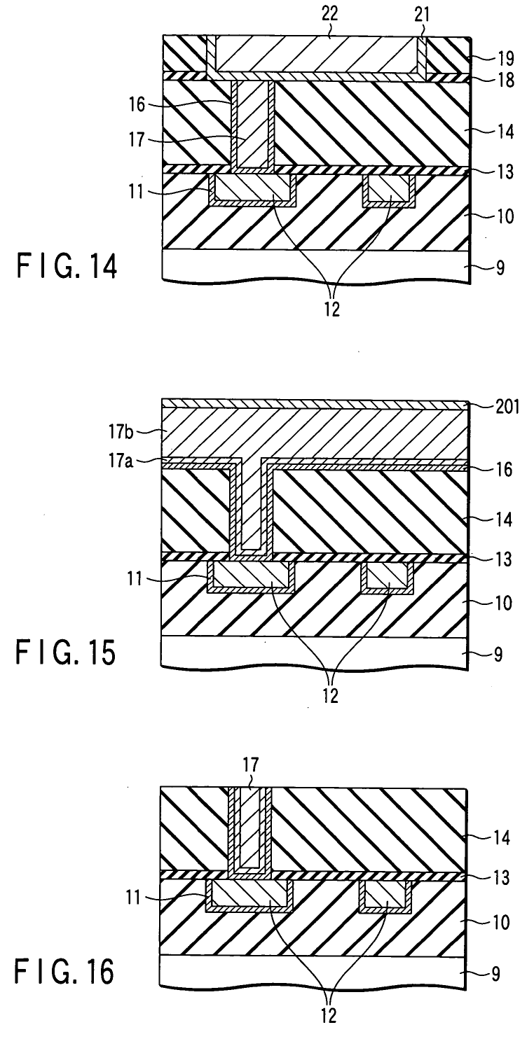

Then, a Cu film of about 400 nm is deposited over the surface of the third interlayer insulating film 19 including the inside of the wiring groove 20 by the electrolytic plating method. Thereafter, the whole Cu film is flattened by using the CMP method and the Cu film is left only in the second wiring groove as a second Cu wiring layer 22, as shown in FIG. 14. Because Sn in the CuSn(1%) film 22a is added in the second Cu wiring layer 22 left in the second wiring groove, this is substantially equivalent to the fact that Sn(1%) is added.

Subsequently, it is possible to form a plurality of multilayer wirings more than two wirings by depositing a diffusion preventive film (not shown) and repeating the above-mentioned steps while referring to FIGS. 12 to 14.

In the embodiment, the at least one additive contained in the metal wiring material of the upper wiring layer (second Cu wiring 22) and the metal wiring material of the lower wiring layer (first Cu wiring 12) is Sn, and the at least two additives contained in the metal wiring material of the via contact 17 are Sn and Rh.

Other additives can be used as the at least one additive. Specifically, when a wiring material is Cu, any of the following substances shown in FIG. 7 is used as an additive: Rh, Zn, Al, Ru, Cr, Pd, In, Mg, Co, Zr, Ti, Ag, Ir, Ni, Ge, Nb, B, and Hf. It is preferable to use one of Sn, Rh, and Zn by comprehensively considering the easiness for execution and the like.

When Al is used as a metal wiring material, it is preferable to use as the at least one additive Cu or Si by comprehensively considering the magnitude of the resistivity and the easiness of introduction into the actual fabrication process.

Moreover, when Ag is used as a metal wiring material, it is preferable to use as the at least one additive Cu by comprehensively considering the magnitude of the resistivity and the easiness of introduction into the actual fabrication process.

<Third Embodiment>

As with the first and second embodiments, this embodiment describes a case of forming an embedded metal wiring by using a single-damascene process.

In the embodiment, the via contact 17, the metal wiring material of the upper wiring layer (second Cu wiring 22) and the metal wiring material of the lower wiring layer (first Cu wiring 12) contain the same additive. The concentration of the additive in the via contact 17 is higher than the concentration of the additive in the first and second wiring layers. The additive may be Si.

When Sn is used as the same additive, the forming process of the first wiring layer and the second wiring layer is the same as that of the second embodiment, and the description is omitted. As with the second embodiment, the amount of Sn added in Cu as a seed-metal in each of the forming processes of the first and second wiring layers 12 and 22 is 1%, for example. Also, as with the second embodiment, a CuSn(1%) film is deposited to a thickness of about 100 nm by the sputter method.

A forming process of the via contact 17 will be described referring to FIGS. 9 to 11.

After the first wiring layers 12 is formed, as shown in FIG. 9, a first diffusion preventive film (e.g. SiN film or SiC film) 13 having an etching stopper function, a Cu diffusion preventive function, and a Cu oxidation preventive function is deposited over the surface of the semiconductor substrate 9, that is, on the first wiring groove and the first interlayer insulating film 10. Then, a second interlayer insulating film (e.g. TEOS film) 14 is deposited over the first diffusion preventive film (e.g. SiN film or SiC film) 13.

Subsequently, a resist is applied onto the second interlayer insulating film 14 and patterned to form a resist pattern, not shown, and a via hole 15 is formed in the second interlayer insulating film 14 by the RIE using the formed resist pattern as a mask. Then, the formed resist pattern is removed. Next, the first diffusion preventive film 13 at the bottom of the via hole 15 is removed by etching.

Then, as shown in FIG. 10, a refractory metal (e.g. Ta film, TaN film, or TiN) is deposited over the surface of the semiconductor substrate 9 as a first barrier metal 16 (a barrier metal of the via contact portion) up to a thickness of about 20 nm by the sputtering method. Moreover, CuSn(2%) obtained by adding 2%, for example, of Sn into Cu is deposited up to a thickness of about 100 nm as a seed metal of the via contact portion by the sputtering method. In this case, Sn can be easily added into Cu by adding Sn into a target metal by the sputtering method. The quantity of Sn to be added must be kept in the tolerance of the increased value of a wiring resistance due to addition of Sn.

Subsequently, the refractory metal film 16 and CuSn(2%) film 17a on the second interlayer insulating film 14 are removed by the CMP method or the like, and the films 16 and 17a are left only on an inside wall of the contact hole 15 as the first barrier metal 16 and the seed metal 17a of the via contact portion, respectively.

Next, as shown in FIG. 11, a Cu film of about 400 nm is deposited over the surface of the semiconductor substrate 9, that is, on the second interlayer insulating film 14 including the inside of the via hole 15 by the electrolytic plating method. Then, the whole Cu film is flattened by the CMP method and the Cu film on the second interlayer insulating film 14 is removed and the Cu film is left only in the via hole 15 as a via contact 17. At this Cu deposition, Sn in the CuSn(2%) film 17a are diffused into the via contact 17. This is substantially equivalent to the fact that Sn are added.

Thereafter, a second diffusion preventive film (e.g. SiN film or SiC film) 18 having an etching stopper function, a Cu diffusion preventive function, and a Cu oxidation preventive function is deposited over the surface of the semiconductor substrate 9, that is, on the via contact 17 and second interlayer insulating film 14.

Subsequently, it is possible to form a plurality of multilayer wirings more than two wirings by depositing a diffusion preventive film (not shown) and repeating the above-mentioned steps while referring to FIGS. 12 to 14.

In this embodiment, Similarly to the second embodiment, the amount of Sn added in Cu as a seed-metal in each of the forming processes of the first and second wiring layers 12 and 22 is 1%. On the other hand, the amount of Sn added in Cu as a seed-metal in the forming processes of the via contact 17 is 2%. example.

Sn(1%) added in the seed-metal in each of the forming processes of the first wiring layer 12 and the second wiring layer 22 is diffused into the first wiring layer 12 and the second wiring layer 22 in each of the forming processes of the first wiring layer 12 and the second wiring layer 22, and Sn(2%) added in the seed-metal in the forming processes of the via contact 17 is diffused into the via contact 17 in the forming processes of the via contact 17. As the result, the concentration of Sn added in the via contact 17 is higher than the concentration of Sn added in the first wiring layer and the second wiring layer.

In the embodiment, Sn is used as the additive contained in the metal wiring material of the first wiring layer and the second wiring layer and the metal wiring material of the in the via contact 17.

Other additives can be used in place of Sn. Specifically, when a wiring material is Cu, any of the following substances shown in FIG. 7 is used as the additive: Rh, Zn, Al, Ru, Cr, Pd, In, Mg, Co, Zr, Ti, Ag, Ir, Ni, Ge, Nb, B, and Hf. It is preferable to use one of Sn, Rh, and Zn by comprehensively considering the easiness for execution and the like.

When Al is used as a metal wiring material, it is preferable to use Cu or Si by comprehensively considering the magnitude of the resistivity and the easiness of introduction into the actual fabrication process.

Moreover, when Ag is used as a metal wiring material, it is preferable to use Cu by comprehensively considering the magnitude of the resistivity and the easiness of introduction into the actual fabrication process.

<Fourth Embodiment>

As with the first, second and third embodiments, this embodiment describes a case of forming an embedded metal wiring by using a single-damascene process.

In the embodiment, the metal wiring material of the upper wiring layer (second Cu wiring 22) and the metal wiring material of the lower wiring layer (first Cu wiring 12) contain at least one additive. The metal wiring material of the via contact 17 contains at least two additives including the same additive or additives as the metal wiring materials of the upper wiring layer and the lower wiring layer. The at least two additives are of different kinds or types. Concentration of one additive which is commonly contained in the upper wiring layer, the lower wiring layer and the via contact is higher in the via contact than in the upper wiring layer and the lower wiring layer.

When Sn is used as the at least one additive, the forming process of the first wiring layer and the second wiring layer is the same as that of the second and third embodiments, and the description is omitted. As with the second embodiment, Sn added in Cu as a seed-metal in each of the forming processes of the first and second wiring layers 12 and 22 is 1%, for example. Also, as with the second and third embodiments, an CuSn(1%) film is deposited to a thickness of about 100 nm by the sputtering method in each of the first wiring layers 12 and the second wiring layer 22

A forming process of the via contact 17 will be described referring to FIGS. 9 to 11.

After the first wiring layers 12 is formed, as shown in FIG. 9, a first diffusion preventive film (e.g. SiN film or SiC film) 13 having an etching stopper function, a Cu diffusion preventive function, and a Cu oxidation preventive function is deposited over the surface of the semiconductor substrate 9, that is, on the first wiring groove and the first interlayer insulating film 10. Then, a second interlayer insulating film (e.g. TEOS film) 14 is deposited over the first diffusion preventive film (e.g. SiN film or SiC film) 13.

Subsequently, a resist is applied onto the second interlayer insulating film 14 and patterned to form a resist pattern, not shown, and a via hole 15 is formed in the second interlayer insulating film 14 by the RIE using the formed resist pattern as a mask. Then, the formed resist pattern is removed. Next, the first diffusion preventive film 13 at the bottom of the via hole 15 is removed by etching.

Then, as shown in FIG. 10, a refractory metal (e.g. Ta film, TaN film, or TiN) is deposited over the surface of the semiconductor substrate 9 as a first barrier metal 16 (a barrier metal of the via contact portion) up to a thickness of about 20 nm by the sputtering method. Moreover, CuSn(2%)Rh(2%) obtained by adding 2%, for example, of Sn and Rh into Cu is deposited up to a thickness of about 100 nm as a seed metal of the via contact portion by the sputtering method. In this case, Sn and Rh can be easily added into Cu by adding Sn and Rh into a target metal by the sputtering method. The quantity of Sn and Rh to be added must be kept in the tolerance of the increased value of a wiring resistance due to addition of Sn and Rh.

Subsequently, the refractory metal film 16 and CuSn(2%) Rh(2%) film 17a on the second interlayer insulating film 14 are removed by the CMP method or the like, and the films 16 and 17a are left only on an inside wall of the contact hole 15 as the first barrier metal 16 and the seed metal 17a of the via contact portion, respectively.

Next, as shown in FIG. 11, a Cu film of about 400 nm is deposited over the surface of the semiconductor substrate 9, that is, on the second interlayer insulating film 14 including the inside of the via hole 15 by the electrolytic plating method. Then, the whole Cu film is flattened by the CMP method and the Cu film on the second interlayer insulating film 14 is removed and the Cu film is left only in the via hole 15 as a via contact 17. At this Cu deposition, Sn(2%) and Rh(2%) in the CuSn(2%)Rh(2%) film 17a are diffused into the via contact 17. This is substantially equivalent to the fact that Sn(2%) and Rh(2%) are added.

Thereafter, a second diffusion preventive film (e.g. SiN film or SiC film) 18 having an etching stopper function, a Cu diffusion preventive function, and a Cu oxidation preventive function is deposited over the surface of the semiconductor substrate 9, that is, on the via contact 17 and second interlayer insulating film 14.

Subsequently, it is possible to form a plurality of multilayer wirings more than two wirings by depositing a diffusion preventive film (not shown) and repeating the above-mentioned steps while referring to FIGS. 12 to 14.

In this embodiment, as described above, the same additive is added in the Cu as a seed-metal in the forming processes of the via contact 17 and the Cu as a seed-metal in each of the forming processes of the first and second wiring layers 12 and 22. The same additive is Sn in the embodiment. Also, in the embodiment, Rn is added in the Cu as the seed-metal in the forming processes of the via contact 17. Rn is not added in the Cu as the seed-metal in each of the forming processes of the first and second wiring layers 12 and 22.

Also, in this embodiment, Similarly to the second and third embodiments, the amount of Sn added in Cu as a seed-metal in each of the forming processes of the first and second wiring layers 12 and 22 is 1%. On the other hand, the amount of Sn added in Cu as a seed-metal in the forming processes of the via contact 17 is 2%. Sn(1%) added in the seed-metal in each of the forming processes of the first wiring layer 12 and the second wiring layer 22 is diffused into the first wiring layer 12 and the second wiring layer 22 in each of the forming processes of the first wiring layer 12 and the second wiring layer 22, and Sn(2%) added in the seed-metal in the forming processes of the via contact 17 is diffused into the via contact 17 in the forming processes of the via contact 17. As the result, the concentration of Sn added in the via contact 17 is higher than the concentration of Sn added in the first wiring layer and the second wiring layer.

In the embodiment, the at least one additive contained in the metal wiring material of the upper wiring layer (second Cu wiring 22) and the metal wiring material of the lower wiring layer (first Cu wiring 12) is Sn, and the at least two additives contained in the metal wiring material of the via contact 17 are Sn and Rh. The concentration of the at least one additive is higher in the via contact 17 than in the metal wiring material of the upper wiring layer (second Cu wiring 22) and the metal wiring material of the lower wiring layer (first Cu wiring 12).

Other additives can be used as the at least one additive. Specifically, when a wiring material is Cu, any of the following substances shown in FIG. 7 is used as an additive: Rh, Zn, Al, Ru, Cr, Pd, In, Mg, Co, Zr, Ti, Ag, Ir, Ni, Ge, Nb, B, and Hf. It is preferable to use one of Sn, Rh, and Zn by comprehensively considering the easiness for execution and the like.

When Al is used as a metal wiring material, it is preferable to use as the at least one additive Cu and Si by comprehensively considering the magnitude of the resistivity and the easiness of introduction into the actual fabrication process.

Moreover, when Ag is used as a metal wiring material, it is preferable to use as the at least one additive Cu by comprehensively considering the magnitude of the resistivity and the easiness of introduction into the actual fabrication process.

<Fifth Embodiment>

As with the first, second, third and fourth embodiments, this embodiment describes a case of forming an embedded metal wiring by using a single-damascene process. In the embodiment, an additive metal film 201 is formed as an additive source on the via contact forming film 201 (FIG. 15).

Forming of the first metal film 12 is similar to the first embodiment and the description is omitted.

A forming process of the via contact 17 will be described referring to FIGS. 1 to 3, 15 and 16.

After the first wiring layer 12 is formed, as shown in FIG. 1, a first diffusion preventive film (e.g. SiN film or SiC film) 13 having an etching stopper function, a Cu diffusion preventive function, and a Cu oxidation preventive function is deposited over the surface of the semiconductor substrate 9, that is, on the first wiring layer 12 and the first interlayer insulating film 10. Then, a second interlayer insulating film (e.g. TEOS film) 14 is deposited over the first diffusion preventive film (e.g. SiN film or SiC film) 13.

Subsequently, a resist is applied onto the second interlayer insulating film 14 and patterned to form a resist pattern, not shown, and a via hole 15 is formed, as shown in FIG. 1, in the second interlayer insulating film 14 by the RIE using the formed resist pattern as a mask. Then, the formed resist pattern is removed. Next, the first diffusion preventive film 13 at the bottom of the via hole 15 is removed by etching.

Then, as shown in FIG. 2, a refractory metal (e.g. Ta film, TaN film, or TiN) is deposited over the surface of the semiconductor substrate 9 as a first barrier metal 16 (a barrier metal of the via contact portion) up to a thickness of about 20 nm by the sputtering method. Moreover, CuSn(1%) 17a obtained by adding 1%, for example, of Sn into Cu is deposited up to a thickness of about 100 nm as a seed metal of the via contact portion by the sputtering method. In this case, Sn can be easily added into Cu by adding Sn into a target metal by the sputtering method. The quantity of Sn to be added must be kept in the tolerance of the increased value of a wiring resistance due to addition of Sn.

Next, as shown in FIG. 15, a Cu film 17b of about 400 nm is deposited over the surface of the semiconductor substrate 9, that is, on a Cu film 17a including the inside of the via hole 15 by the electrolytic plating method. Then, a metal film 201 containing an additive Sn(1%) is deposited on the Cu film 17b by the sputtering method. Subsequently, a heat treatment is carried out to diffuse Sn contained in the metal film 201 into the via contact portion 17 of the Cu film 17b. As the result, the via contact portion 17 of the Cu film 17b becomes equivalent to the fact that Sn is added. At the diffusion, Sn contained in the metal film 201 is also diffused into the Cu film 17b on the second interlayer insulating film 14. The Cu film 17b on the second interlayer insulating film 14 may be used as an upper wiring layer. The upper wiring layer is formed by the process of the second embodiment.

Then, as shown in FIG. 16, the metal film 201 and the Cu film 17b on the second interlayer insulating film 14 are polished by the CMP method to leave the Cu film 17b only in the via hole 15 as a via contact 17. When the Cu film 17b on the second interlayer insulating film 14 is not used as the upper wiring layer, it is possible that the polishing of the Cu film 17b on the second interlayer insulating film 14 is carried out following the deposition of the Cu film 17b to remove the Cu film 17b on the second interlayer insulating film 14, thus leaving the Cu film 17b only in the via hole 15 as a via contact 17.

Thereafter, as shown in FIG. 3, a second diffusion preventive film (e.g. SiN film or SiC film) 18 having an etching stopper function, a Cu diffusion preventive function, and a Cu oxidation preventive function is deposited over the surface of the semiconductor substrate 9, that is, on the via contact 17 and second interlayer insulating film 14.

Subsequently, it is possible to form a plurality of multilayer wirings more than two wirings by depositing a diffusion preventive film (not shown) and repeating the above-mentioned steps while referring to FIGS. 4 to 6.

Also in the semiconductor device of the multi-wiring structure in which at least two wiring layers 12 and 22 and the via contact 17 provided therebetween, additive Sn is contained in the metal wiring material of the via contact 17. The wiring layers 12 and 22 do not contain Sn. As the result, the resistance against migration in the via contact 17 is improved, while preventing a wiring resistance from increasing.

In place of Sn, any of other following additives can be used as the additive to the metal wiring material of the via contact 17: Rh, Zn, Al, Ru, Cr, Pd, In, Mg, Co, Zr, Ti, Ag, Ir, Ni, Ge, Nb, B, and Hf. It is preferable to use one of Sn, Rh, and Zn by comprehensively considering the easiness for execution and the like.

When Al is used as a metal wiring material, it is preferable to use Cu or Si as the at least one additive by comprehensively considering the magnitude of the resistivity and the easiness of introduction into the actual fabrication process.

Moreover, when Ag is used as a metal wiring material, it is preferable to use as the at least one additive Cu by comprehensively considering the magnitude of the resistivity and the easiness of introduction into the actual fabrication process.

The feature of forming the additive metal film 201 on the via contact forming film according to the embodiment can be applied to other embodiments described herein.

<Sixth Embodiment>

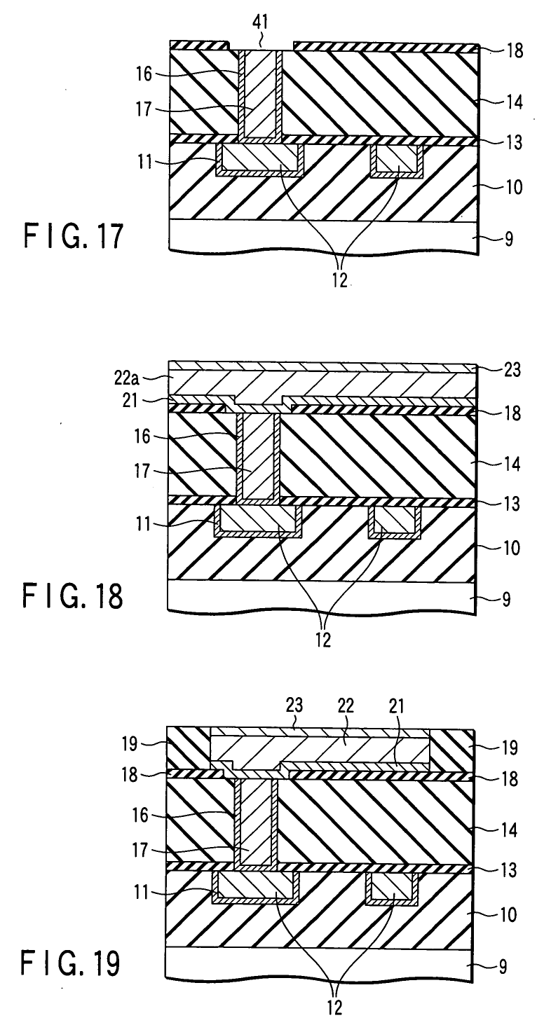

FIGS. 17 to 19 are sectional views of a part of a semiconductor device according to a sixth embodiment of the present invention in steps of fabricating a semiconductor device having a multi-layered metal wiring.

In the case of the first to fifth embodiments, the single damascene process is used to form the wiring layer 22. In the sixth embodiment, selective dry-etching method is used to form the wiring layer 22. Also in this embodiment, the concentration of additive to the via contact is made higher than the concentration of additives to the first and second wiring layers.

An element-separation-structure forming step and a MOSFET forming step are omitted but steps from a step of forming an embedded first Cu wiring up to a step of forming a via contact and a second Cu wiring layer by using the same metal wiring material are disclosed.

First, the steps shown in FIGS. 1 to 3 are executed similarly to the case of the first embodiment.

Next, as shown in FIG. 17, an opening 41 for conduction with a wiring layer to be formed in a later step is formed at a predetermined portion on the second diffusion preventive film 18.

Thereafter, a Ta film, TaN film, or TiN film is deposited over the surface of the semiconductor substrate 9 as a second barrier metal 21 by the sputtering method as shown in FIG. 18. Moreover, a Cu film 22a is deposited by the sputtering method. However, Sn is not added into the Cu film 22a. In addition, after depositing a third barrier metal 23, the third barrier metal 23, Cu film 22a, and second barrier metal 21 are patterned by the normal lithography technique and RIE technique to form a second Cu film 22 as shown in FIG. 19. Further, a third interlayer insulating film 19 is deposited over the surface of the semiconductor substrate 9 and CMP is applied to the deposited third interlayer insulating film 19 to expose the upper face of the second Cu wiring layer 22.

Subsequently, it is possible to form a plurality of multilayer wirings more than two wirings by depositing a diffusion preventive film (not shown) and repeating the above-mentioned steps while referring to FIGS. 17 to 19.

<Seventh Embodiment>

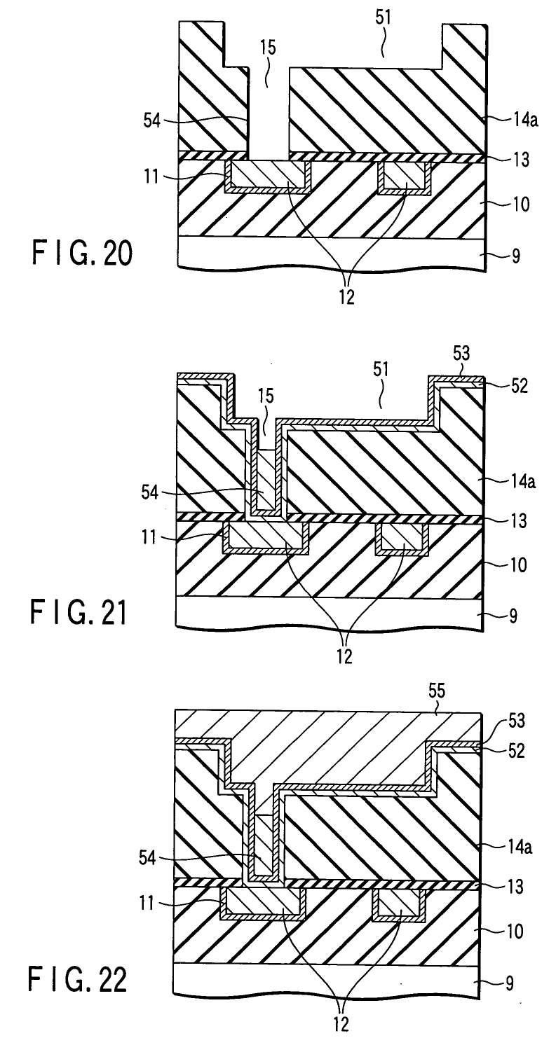

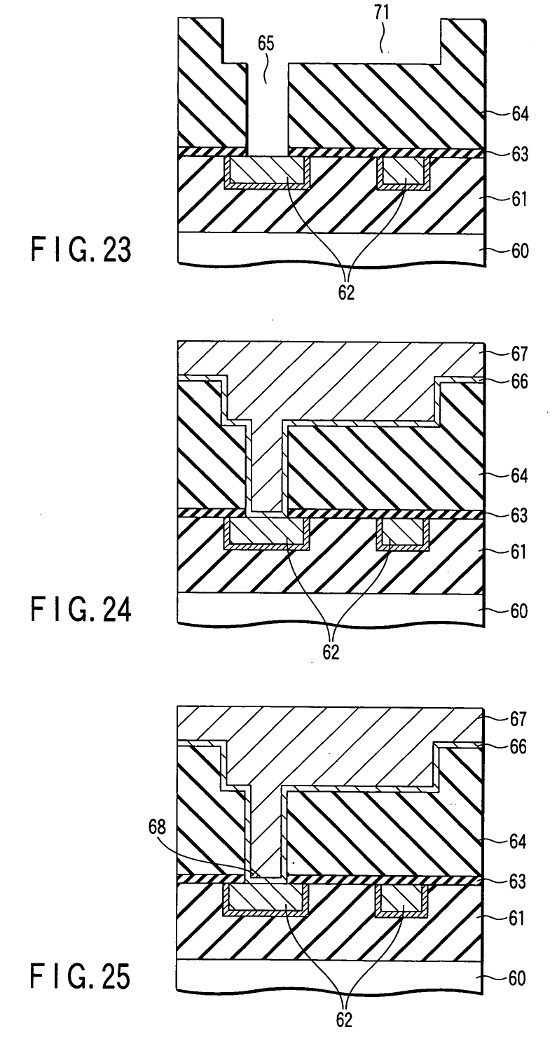

FIGS. 20 to 22 are sectional views of a part of a semiconductor device according to a seventh embodiment of the present invention in steps of fabricating a semiconductor device having a multi-layered metal wiring.

In the case of the first to sixth embodiments, the single damascene process is used to form the wiring layer. In the seventh embodiment, the dual damascene process is used to form the wiring layer. Also in this embodiment, the concentration of additive to the via contact is made higher than the concentration of additives to the first and second wiring layers.

An element-separation-structure forming step and a MOSFET forming step are omitted but steps from a step of forming an embedded first Cu wiring up to a step of forming a via contact and a second Cu wiring layer by using the same metal wiring material are disclosed.

First, a first wiring layer 12 is formed, as shown in FIG. 20. The forming process of the first wiring layer 12 is similar to the case of the first embodiment.

After the first wiring layer 12 is formed, a first diffusion preventive film (e.g. SiN film or SiC film) 13 having an etching stopper function, a Cu diffusion preventive function, and a Cu oxidation preventive function is deposited over the surface of the semiconductor substrate 9, that is, on the first wiring layer 12 and the first interlayer insulating film 10. Then, a second interlayer insulating film (e.g. TEOS film) 14a in which a contact hole and a second Cu wiring layer groove are to be formed is deposited over the first diffusion preventive film (e.g. SiN film or SiC film) 13.

Thereafter, as shown in FIG. 20, a wiring groove 51 is formed in the second interlayer insulating film 14a, and a via hole 15 is formed at a predetermined portion at the bottom of the wiring groove 51 (on the upper portion of the first Cu wiring layer 12) by using the dual damascene process.

Next, the first diffusion preventive film 13 at the bottom of the via hole 15 is removed by etching. Then, as shown in FIG. 21, a Ta film or TaN film is deposited over the surface of the semiconductor substrate 9 as a barrier metal 52 up to a thickness of about 20 nm by the sputtering method. Moreover, a Cu film is deposited up to a thickness of about 100 nm as a seed metal 53 by the sputtering method. Sn is not added into the Cu film 53.

Thereafter, Cu 54 is deposited in the via hole 15 up to the intermediate height of the via hole 15 by the electroless plating method with Cu containing an additive other than Cu. In this case, a condition according to a so-called bottom-up is used, and adding an additive is not used.

Then, as shown in FIG. 22, a Cu film 55 with a thickness of about 400 nm is deposited over the surface of the second interlayer insulating film 14a including the inside of the vial hole 15 and the inside of the wiring groove 51 by the electrolytic plating method. Thereafter, the Cu film 55 is flattened by the CMP method and is left only in the via hole 15 and wiring groove 51 as a Cu wiring layer.

Subsequently, it is possible to form a plurality of multilayer wirings more than two wirings by depositing a diffusion preventive film (not shown) and repeating the above-mentioned steps while referring to FIGS. 20 to 22.

Other embodiments can be realized in the semiconductor device having a multilayer structure constituted by using the same metal wiring material for at least two wiring layers of an upper wiring layer and lower wiring layer and a via contact formed between the upper and lower wiring layers.

In the methods of manufacturing a semiconductor device in the first to sixth embodiments, using the damascene process is described when forming the upper and lower wiring layers and the via contact in different steps. However, it is also possible to form the wiring layer by another method such as the well-known dry etching method. Moreover, in the method of manufacturing a semiconductor device of the seventh embodiment, it is also possible to form additive of the via contact and its upper wiring layer in the same step, e.g. dual damascene process.

In the above manufacturing methods, the step of forming the upper and lower wiring layers and the step of forming the via contact can use at least one of the CVD method, PVD method, electrolytic plating method, and electroless plating method. Also, it is possible to use methods different from each other for the step of forming the wiring layer and the step of forming the via contact.

With the semiconductor device and the manufacturing method according to the above-mentioned embodiments, it is possible to improve the resistance against via migration while preventing a wiring resistance from increasing.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device having a multilayer structure, comprising:
at least two wiring layers; and
a via contact formed between the at least two layers and made of a metal wiring material which is the same as that of the at least two wiring layers,
wherein the metal wiring material of the via contact contains an additive which is not contained in the metal wiring materials of the at least two wiring layers.

2. The semiconductor device according to claim 1, wherein the metal wiring material is Cu and the additive is one of Sn, Rh, Zn, Al, Ru, Cr, Pd, In, Mg, Co, Zr, Ti, Ag, Ir, Ni, Ge, Nb, B, and Hf.

3. The semiconductor device according to claim 1, wherein the metal wiring material is Al and the additive is Cu or Si.

4. The semiconductor device according to claim 1, wherein the metal wiring material is Ag and the additive is Cu.

5. A semiconductor device having a multilayer structure, comprising:
at least two wiring layers; and
a via contact formed between the at least two layers and made of a metal wiring material which is the same as that of the at least two wiring layers,
wherein metal wiring materials of the at least two wiring layers contain at least one additive, and
a metal wiring material of the via contact contains at least two additives which include an additive which is the same as that contained in the metal wiring materials of the at least two wiring layers.

6. The semiconductor device according to claim 5, wherein the metal wiring material is Cu and the at least one additive is one of Sn, Rh, Zn, Al, Ru, Cr, Pd, In, Mg, Co, Zr, Ti, Ag, Ir, Ni, Ge, Nb, B, and Hf.

7. A semiconductor device having a multilayer structure, comprising:
at least two wiring layers; and
a via contact formed between the at least two layers and made of a metal wiring material which is the same as that of the at least two wiring layers,
wherein metal wiring materials of the at least two wiring layers and a metal wiring material of the via contact contain the same additive, and
a concentration of the same additive in metal wiring material of the via contact is higher than that of the same additive in the metal wiring materials of the at least two wiring layers.

8. The semiconductor device according to claim 7, wherein the metal wiring material is Cu and the at least one additive is one of Sn, Rh, Zn, Al, Ru, Cr, Pd, In, Mg, Co, Zr, Ti, Ag, Ir, Ni, Ge, Nb, B, and Hf.

9. A semiconductor device having a multilayer structure, comprising:
at least two wiring layers; and
a via contact formed between the at least two layers and made of a metal wiring material which is the same as that of the at least two wiring layers,
wherein metal wiring materials of the at least two wiring layers contain at least one additive, and
a metal wiring material of the via contact contains at least two additives which include an additive which is the same as that contained in the metal wiring materials of the at least two wiring layers, and
a concentration of the at least one additive commonly contained in the metal wiring materials of the at least two wiring layers and the metal wiring material of the via contact is higher in the metal wiring material of the via contact than in the metal wiring materials of the at least two wiring layers.

10. The semiconductor device according to claim 9, wherein the metal wiring material is Cu and the at least one additive commonly contained is one of Sn, Rh, Zn, Al, Ru, Cr, Pd, In, Mg, Co, Zr, Ti, Ag, Ir, Ni, Ge, Nb, B, and Hf.

11. A semiconductor device comprising:
a first metal wiring layer made of a first wiring material, formed in a first wiring groove formed in a first insulating film on a semiconductor substrate;
a second insulating film on the first insulating film having the first wiring layer embedded therein;
a via contact embedded in a via hole formed in the second insulating film, the via contact being made of the same wiring material as the first wiring material, which contain an additive which is not contained in the first wiring material of the first wiring layer;
a third insulating film on the second insulating film having the via contact formed therein; and
a second metal wiring layer embedded in a second wiring groove formed in the third insulating film, the second metal wiring layer being made of the same metal wiring material as the metal wiring material of the first metal wiring layer.

12. The semiconductor device according to claim 11, wherein the metal wiring material is Cu and the additive contained in the metal wiring material is one of Sn, Rh, Zn, Al, Ru, Cr, Pd, In, Mg, Co, Zr, Ti, Ag, Ir, Ni, Ge, Nb, B, and Hf.

13. A semiconductor device comprising:
a first metal wiring layer made of a first wiring material added with an additive, formed in a first wiring groove formed in a first insulating film on a semiconductor substrate;
a second insulating film on the first insulating film having the first wiring layer embedded therein;
a via contact embedded in a via hole formed in the second insulating film, the via contact being made of the first wiring material which contains the additive; and
a third insulating film on the second insulating film having the via contact formed therein; and
a second metal wiring layer embedded in a second wiring groove formed in the third insulating film, the second metal wiring layer being made of the metal wiring material which contains the additive,
wherein a concentration of the additive in the metal wiring material of the via contact is higher than that of the additive in the metal wiring materials of the first metal wiring layer and the second metal wiring layer.

14. The semiconductor device according to claim 13, wherein the metal wiring material is Cu and the additive is one of Sn, Rh, Zn, Al, Ru, Cr, Pd, In, Mg, Co, Zr, Ti, Ag, Ir, Ni, Ge, Nb, B, and Hf.

15. A method of manufacturing a semiconductor device, comprising:
forming a first wiring layer made of a metal wiring material in a first wiring groove formed in a first insulating film on a semiconductor substrate;
forming a second insulating film on the first insulating film having the first wiring layer formed therein;
forming a via hole in the second insulating film;
forming a first barrier metal over the surface of the second insulating film including the via hole;
forming a first metal film formed of the metal wiring material over the surface of the first barrier metal to embed the metal wiring material in the via hole;
forming a via contact formed of the first metal film and first barrier metal on the via hole by removing the first metal film and first barrier metal from portions other than the inside of the via hole;
forming a third insulating film over the surface of the second insulating film having the via contact formed thereon;
forming a second wiring groove in the third insulating film;
forming a second barrier metal over the surface of the third insulating film including the second wiring groove;
forming a second metal film formed from the first metal material over the surface of the second barrier metal; and
forming a second wiring layer formed by residual portions of the second metal film and second barrier metal in the second wiring groove by removing the portions of the second metal film and second barrier metal deposited on the third insulating film,
wherein the metal wiring material of the first metal film contains an additive which is not contained in the metal wiring materials of the first wiring layer and the second metal film.

16. A method of manufacturing a semiconductor device, comprising:
forming a first wiring layer made of a metal wiring material added with an additive in a first wiring groove formed in a first insulating film on a semiconductor substrate;
forming a second insulating film on the first insulating film having the first wiring layer formed therein;
forming a via hole in the second insulating film;
forming a first barrier metal over the second insulating film including the via hole;
forming a first metal film made of the metal wiring material added with the additive over the first barrier metal to embed the via hole with the metal wiring material added with the additive;
removing the first metal film and the first barrier metal from portions other than the inside of the via hole to form a via contact formed of the first metal film added with the additive in the via hole;
forming a third insulating film over the surface of the second insulating film having the via contact formed thereon;
forming a second wiring groove in the third insulating film;
forming a second barrier metal over the third insulating film including the second wiring groove;
forming a second metal film made of the metal wiring material added with the additive over the second barrier metal; and
removing the portions of the second metal film and second barrier metal on the third insulating film to form a second wiring layer formed of the second metal film added with the additive in the second wiring groove,
wherein a concentration of the additive in the metal wiring material of the first metal film of the via contact is higher than that of the additive in the metal wiring material of the first wiring layer and the metal wiring material of the second metal film.

17. A method of manufacturing a semiconductor device, comprising:
forming a first wiring layer made of a metal wiring material in a first wiring groove formed in a first insulating film on a semiconductor substrate;
forming a second insulating film on the first insulating film having the first wiring layer formed therein;
forming a via hole in the second insulating film;
forming a first barrier metal over the second insulating film including the via hole;
forming a first metal film made of the metal wiring material over the first barrier metal to embed the via hole with the metal wiring material added with the additive;
removing the first metal film and the first barrier metal from portions other than the inside of the via hole to form a via contact formed of the first metal film in the via hole;
forming a third insulating film over the surface of the second insulating film having the via contact formed thereon;
forming a second wiring groove in the third insulating film;
forming a second barrier metal over the third insulating film including the second wiring groove;
forming a second metal film made of the metal wiring material over the second barrier metal; and
removing the portions of the second metal film and second barrier metal on the third insulating film to form a second wiring layer formed of the second metal film in the second wiring groove,
wherein metal wiring materials of the first wiring layer and the second wiring layer contain at least one additive, and
the metal wiring material of the first metal film contains at least two additives which include the at least one additive.

18. A method of manufacturing a semiconductor device, comprising:
forming a first wiring layer made of a metal wiring material in a first wiring groove formed in a first insulating film on a semiconductor substrate;
forming a second insulating film on the first insulating film having the first wiring layer formed therein;
forming a via hole in the second insulating film;
forming a first barrier metal over the second insulating film including the via hole;
forming a first metal film made of the metal wiring material over the first barrier metal to embed the via hole with the metal wiring material;
removing the first metal film and the first barrier metal from portions other than the inside of the via hole to form a via contact formed of the first metal film in the via hole;
forming a third insulating film over the surface of the second insulating film having the via contact formed thereon;
forming a second wiring groove in the third insulating film;
forming a second barrier metal over the third insulating film including the second wiring groove;
forming a second metal film made of the metal wiring material over the second barrier metal to embed the second wiring groove with the metal wiring material; and
removing the portions of the second metal film and second barrier metal on the third insulating film to form a second wiring layer formed of the second metal wiring layer in the second wiring groove,
wherein metal wiring materials of the first wiring layer and the second wiring layer contain at least one additive, and
the metal wiring material of the first metal film contains at least two additives which include the at least one additive.
wherein a concentration of the at least one additive in the metal wiring material of the first metal film is higher than that of the at least one additive in the metal wiring material of the first wiring layer and the metal wiring material of the second metal film.

19. A method of manufacturing a semiconductor device, comprising:
forming a first wiring layer made of a metal wiring material in a first wiring groove formed in a first insulating film on a semiconductor substrate;
forming a second insulating film on the first insulating film having the first wiring layer formed therein;
forming a via hole in the second insulating film;
forming a first barrier metal over the second insulating film including the via hole;
forming a first metal film made of the metal wiring material over the first barrier metal to embed the via hole with the metal wiring material;
forming a substance layer containing an additive which is not contained in the metal wiring material of the first wiring layer over the first metal film;
heating to diffuse the additive contained in the substance layer into first metal film;
removing the substance layer as well as the first metal film and the first barrier metal from portions other than the inside of the via hole to form a via contact formed of the first metal film containing the additive in the via hole;
forming a third insulating film over the surface of the second insulating film having the via contact formed thereon;
forming a second wiring groove in the third insulating film;
forming a second barrier metal over the third insulating film including the second wiring groove;
forming a second metal film made of the metal wiring material over the second barrier metal; and
removing the portions of the second metal film and second barrier metal on the third insulating film to form a second wiring layer formed of the second metal film in the second wiring groove.
